(19) United States
(12) Patent Application Publication
(10) Pub. No.: US 2026/0260690 A1
(43) Pub. Date: Sep. 3, 2026

(54) DYNAMIC CONTROL OF RESISTIVE RANDOM-ACCESS MEMORY

(71) Applicant: University of South Alabama, Mobile, AL (US)

(72) Inventors: Jinhui Wang, Mobile, AL (US); Rafeeq Khan Mohammed, Mobile, AL (US)

(73) Assignee: University of South Alabama, Mobile, AL (US)

(21) Appl. No.: 19/553,785

(22) Filed: Mar. 2, 2026

Related U.S. Application Data
(60) Provisional application No. 63/765,848, filed on Mar. 3, 2025.

(51) Int. Cl. G11C 13/00; H03M 1/66

(52) U.S. Cl. CPC G11C 13/0069; G11C 13/0061; H03M 1/66

(57) ABSTRACT

A resistive random-access memory (ReRAM) memory cell array is accessed. A variable pulse width primeval signal is generated using a pulse width modulator. The variable pulse width primeval signal is generated at an initial voltage, and a width of the variable pulse width primeval signal determines a duration of a variable pulse width programming signal. The initial voltage of the variable pulse width primeval signal is adjusted based on a binary digital input and a ReRAM memory cell array supply voltage, and the adjusting determines an output voltage of the variable pulse width programming signal. The variable pulse width programming signal is routed to a portion of the ReRAM memory cell array, based on a ReRAM operation, and the portion of the ReRAM memory cell array is programmed using the variable pulse width programming signal that was routed.

### RELATED APPLICATIONS

This application claims the benefit of U.S. provisional patent application “Dynamic Control Of Resistive Random-Access Memory” Ser. No. 63/765,848, filed March 3, 2025.

The Foregoing Application is hereby Incorporated by reference in its entriety.

### STATEMENT REGARDING FEDERALLY SPONSORED RESEARCH OR DEVELOPMENT

This invention was made with government support under 2427766, 2420994, 2247343, and 2346905 awarded by the National Science Foundation. The government has certain rights in the invention.

### FIELD OF ART

This application relates generally to computer memory and more particularly to dynamic control of resistive random-access memory.

### BACKGROUND

Storing data in computer memory is important for enabling a wide range of applications. These applications can include productivity software such as word processing applications and spreadsheets. The applications can include messaging and collaboration applications that include chat, video conferencing, and screen sharing capabilities. Web browsers and media players are also essential tools for accessing the internet and consuming various types of media content.

Computer memory, such as random-access memory (RAM), provides much faster access times compared to other storage types such as hard drives or solid-state disks (SSDs). This increase in access speed is essential for the efficient execution of programs and quick data retrieval, which enhances overall system performance. Moreover, ensuring data integrity and reliability is vital. Memory technologies must be able to store data accurately and retrieve it without errors. This is particularly important in critical applications such as medical devices, financial systems, and aerospace technology, where data corruption can have severe consequences.

Data in computer memory is typically stored in a structured and organized manner to ensure efficient access and manipulation. The word size refers to the number of bits processed by a computer processor in one operation. Common word sizes include 8-bit, 16-bit, 32-bit, and 64-bit. The word size determines the amount of data the processor can handle at once and influences the overall performance and memory addressing capabilities of the system. In general, memory can be organized into a series of addresses, each capable of storing a word of data. These addresses are used to locate and access specific data within the memory.

As electronic devices become more portable and energy efficient, memory technologies with low power consumption are increasingly important. Low-power memory extends battery life in mobile devices and reduces energy costs in data centers, contributing to more sustainable technology use. Low-power computer memories have enabled a wide range of applications and devices, enhancing their efficiency and functionality. Low-power memory technologies are crucial for smartphones. They provide the necessary bandwidth and capacity for advanced features such as AI-powered applications, high-resolution video streaming, and gaming, all while conserving battery life. Moreover, IoT devices like smart thermostats, security cameras, and smart speakers rely on low-power memory to operate efficiently over long periods without frequent recharging or battery replacement. Other devices such as fitness trackers and smartwatches can use low-power memory to monitor health metrics continuously while maintaining a compact form factor and long battery life.

Advancements in computer memory technologies are poised to bring numerous benefits in the future, impacting various aspects of computing and electronic devices. Faster data access can enhance the speed and efficiency of applications, from gaming to data-intensive tasks like AI and machine learning. Improved storage capabilities can enable higher storage densities, allowing for more data to be stored in smaller physical spaces. This will be useful for handling the growing volumes of data generated by modern applications and services. Advancements in memory technologies that focus on reducing power consumption are beneficial for portable devices such as smartphones and laptops. Low-power memory can extend battery life, making electronic devices more convenient and sustainable. With faster and more efficient memory, users will experience smoother multitasking and quicker application load times. This can enhance productivity and provide a more responsive computing experience. Overall, advancements in computer memory technologies continue to drive innovation across various industries, leading to more powerful, efficient, and reliable computing systems.

### SUMMARY

Storage technologies that can store data with little or no power consumption offer several key benefits. In devices such as smartphones, tablets, and laptops, low-power storage extends battery life, allowing users to work, play, and communicate for longer periods of time without needing to recharge. Reducing power consumption in storage technologies helps data centers lower their energy usage and operational costs. This contributes to more sustainable and environmentally friendly computing infrastructure. Devices deployed in remote or hard-to-reach locations, such as environmental sensors and industrial IoT devices, benefit from low-power storage as it ensures continuous operation without frequent maintenance or battery replacement. Additionally, lower power consumption generates less heat, which is important for maintaining the stability and longevity of electronic components. This is particularly important in densely packed environments like data centers and high-performance computing systems. Furthermore, storage technologies that require little or no power are often more robust and can withstand harsh conditions, such as extreme temperatures and radiation. This robustness makes them suitable for use in aerospace, military, and industrial applications. Moreover, reduced power consumption can translate to lower electricity bills and cooling costs, providing significant savings over time for both consumers and businesses.

Techniques for memory control are disclosed. The techniques include accessing a resistive random-access memory (ReRAM) memory cell array. A variable pulse width primeval signal is generated using a pulse width modulator. The variable pulse width primeval signal is generated at an initial voltage, and a width of the variable pulse width primeval signal determines a duration of a variable pulse width programming signal. The initial voltage of the variable pulse width primeval signal is adjusted based on a binary digital input and a ReRAM memory cell array supply voltage, and the adjusting determines an output voltage of the variable pulse width programming signal. The variable pulse width programming signal is routed to a portion of the ReRAM memory cell array, based on a ReRAM operation, and the portion of the ReRAM memory cell array is programmed using the variable pulse width programming signal that was routed.

A method for memory control is disclosed comprising: accessing a resistive random-access memory (ReRAM) memory cell array; generating a variable pulse width primeval signal, wherein the variable pulse width primeval signal is generated using a pulse width modulator, wherein the variable pulse width primeval signal is generated at an initial voltage, and wherein a width of the variable pulse width primeval signal determines a duration of a variable pulse width programming signal; adjusting the initial voltage of the variable pulse width primeval signal, wherein the initial voltage is adjusted based on a binary digital input and a ReRAM memory cell array supply voltage, and wherein the adjusting determines an output voltage of the variable pulse width programming signal; routing the variable pulse width programming signal to a portion of the ReRAM memory cell array, based on a ReRAM operation; and programming the portion of the ReRAM memory cell array, using the variable pulse width programming signal that was routed. In embodiments, the routing the variable pulse width programming signal enables control of a ReRAM memory cell array wordline, a ReRAM memory cell array bitline, and a ReRAM memory cell array select line. In embodiments, control of the ReRAM memory cell array wordline, the ReRAM memory cell array bitline, and the ReRAM memory cell array select line is managed by logic blocks comprising the same generating, adjusting, and routing functionality. In embodiments, the generating, the adjusting, and the routing are determined dynamically on a per programming operation basis.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for dynamic control of resistive random-access memory.

FIG. 2 is a flow diagram for resistive random-access memory operations.

FIG. 3 is a system block diagram for dynamic control of resistive random-access memory.

FIG. 4 is a system block diagram for resistive random-access memory pulse width generation.

FIG. 5 is a system block diagram for resistive random-access memory amplitude adjusting using a digital-analog converter (DAC).

FIG. 6 is a system block diagram for resistive random-access memory routing control.

FIG. 7 is a system diagram for dynamic control of resistive random-access memory.

FIG. 8 is a design flow for semiconductor logic generation.

### DETAILED DESCRIPTION

Resistive RAM (ReRAM) is a type of non-volatile memory that stores data by changing the resistance of a material within a memory cell. ReRAM exploits a phenomenon referred to as resistive switching, in which the resistance of a material can be altered by applying an electric voltage or current. The material switches between a Low-Resistance State (LRS) and a High-Resistance State (HRS). A ReRAM cell can include a top electrode and a bottom electrode that sandwich a resistive switching layer. The resistive switching layer can be comprised of materials such as metal oxides, including HfO₂, TiO₂, and/or other suitable metal oxides. The resistive switching layer is where the resistance change occurs. The resistance change can be caused by the formation and dissolution of conductive filaments in the switching layer. The filaments may have a conical shape or exhibit irregular shapes, such as fractal-like growth. In some cases, the filaments may have a length based on the fabrication technology, and in some cases, can range in length from 5 nanometers to 20 nanometers.

Some ReRAM cells may utilize a one-time initialization process, referred to as a forming process. Forming is a process where an initial voltage (called the “forming voltage”) is applied to a ReRAM cell to create conductive paths (filaments) within the resistive switching material. The resistive switching layer in a new cell can be in a pristine, uniform state. The forming process introduces defects or conductive filaments (e.g., due to the movement of oxygen ions and/or metal ions), which enable resistive switching. The forming process can create oxygen vacancies, ion migration pathways, and/or structural changes in materials such as HfO₂ or TiO₂. These defects serve to enable repeatable resistive switching. The forming step activates the cell, enabling it to switch between the high-resistance state (HRS) and low-resistance state (LRS) during normal operation. Thus, in a ReRAM device, the filaments can dissolve (RESET state) and re-form (SET state) dynamically during memory operations.

In disclosed implementations, for forming, a relatively high voltage (higher than normal operating voltages) is applied across the ReRAM memory cell array. This voltage is controlled to prevent damage to the device. Disclosed implementations may include a current compliance limit to avoid excessive current that could permanently damage the ReRAM memory cell array. The forming process transitions the resistive switching material into a ready state, where the ReRAM memory cell array can now toggle between LRS and HRS in order to enable storage and retrieval of data.

Techniques for memory control are disclosed. The techniques include accessing a resistive random-access memory (ReRAM) memory cell array. A variable pulse width primeval signal is generated using a pulse width modulator. The variable pulse width primeval signal is generated at an initial voltage, and a width of the variable pulse width primeval signal determines a duration of a variable pulse width programming signal. The initial voltage of the variable pulse width primeval signal is adjusted based on a binary digital input and a ReRAM memory cell array supply voltage, and the adjusting determines an output voltage of the variable pulse width programming signal. The variable pulse width programming signal is routed to a portion of the ReRAM memory cell array, based on a ReRAM operation, and the portion of the ReRAM memory cell array is programmed using the variable pulse width programming signal that was routed.

A memory controller plays a crucial role in managing resistive RAM (ReRAM) memory cells, particularly because ReRAM technology can exhibit significant variability across different manufacturers and even between batches due to manufacturing process variations. Different manufacturers can develop ReRAM with varying material compositions, switching mechanisms, and endurance characteristics. For example, some ReRAM cells may use oxide-based switching, while others rely on conductive-bridge mechanisms, leading to differences in voltage thresholds and response times. The time required for forming filaments in ReRAM cells can depend on various factors, such as material composition, applied voltages, and operating temperatures. The filament forming time can take place over the range of nanoseconds to microseconds for modern ReRAM technology. Disclosed implementations can accommodate this wide range of filament forming times and provide a flexible memory controller that enables compatibility with a broader range of ReRAM suppliers, reducing dependency on a single source. Moreover, even within the same ReRAM technology, variations in the manufacturing process can lead to differences in forming voltages, setting voltages, and/or resetting voltages. Disclosed implementations provide a memory controller that can adjust operating parameters to compensate for these differences in order to accommodate a wide variety of ReRAM cells. The memory controller of disclosed implementations enables electronic device manufacturers to source ReRAM chips from multiple vendors without needing to redesign the memory controller. Thus, disclosed implementations can serve to reduce costs, enhance supply chain flexibility, and mitigate risks from supply shortages.

ReRAM technology can provide numerous advantages as compared to flash memory, battery-backed SRAM, and/or other non-volatile storage solutions. In comparing ReRAM with flash memory, the ReRAM can typically provide faster write speeds, improved endurance, and reduced power consumption. Moreover, ReRAM technology is well suited for 3D-stacking. ReRAM memory cells are made of a resistive switching layer sandwiched between two electrodes. This structure is simpler and more compact than traditional floating-gate flash or capacitor-based FeRAM, making it easier to stack multiple layers. Furthermore, unlike flash memory, ReRAM does not require high-voltage transistors or complex peripheral circuitry, allowing for more straightforward 3D stacking. With 3D stacking, instead of a single memory layer, multiple layers of ReRAM cells can be stacked vertically on a chip. This increases memory capacity without increasing the chip’s footprint, making it possible to fit terabytes of non-volatile memory into a compact form factor. Moreover, since ReRAM consumes significantly less power per operation than other memory technologies, it enables the fabrication of high-density ReRAM stacks that are thermally manageable.

The advantages provided by ReRAM technology, including the increased memory density of 3D devices, can support a wide range of applications. As an example, rapid advancements in artificial intelligence (AI), particularly in deep learning and large language models, are placing increasing demands on computing resources. AI workloads require vast amounts of memory to store and process large datasets efficiently, with high-speed access to intermediate computations and model parameters. Traditional memory technologies, such as DRAM and NAND flash, are facing challenges in terms of power consumption, scalability, and latency, making it essential to develop new, more efficient memory solutions. The need for high-bandwidth, low-latency, and energy-efficient memory has become an important factor in advancing AI performance, as models continue to grow in complexity and size. AI workloads require massive amounts of fast, non-volatile memory for training and inference. 3D-stacked ReRAM enables high-speed local memory proximal to AI processors, reducing data transfer bottlenecks.

Resistive RAM (ReRAM) is emerging as a key technology to address these challenges, offering non-volatile, high-density, and low-power memory capabilities that are well suited for AI applications. Unlike conventional memory, ReRAM can retain data without continuous power and supports fast, in-memory computing architectures that reduce data transfer bottlenecks. The capability of ReRAM to enable 3D stacking can further enhance memory density, allowing AI accelerators to integrate more memory closer to processing units. Additionally, the dynamic programming capabilities of ReRAM, in which programming voltages can be adjusted in real time to ensure reliable operation, make ReRAM adaptable for long-term AI workloads. As AI continues to evolve, memory technologies such as ReRAM may play a crucial role in enabling the next generation of efficient, high-performance computing architectures.

Other applications and devices such as Edge AI and IoT devices also can benefit from the high-density, low-power memory in a compact package that ReRAM can provide. ReRAM enables energy-efficient memory storage to allow edge processing to generate computational results without relying on cloud processing. Another area benefiting from ReRAM technology is medical devices. These devices can include brain-machine interfaces, smart prosthetics, and biosensors that can benefit from the miniaturized, high-capacity storage enabled by ReRAM, for continuous monitoring and AI-driven diagnostics. Thus, the use of ReRAM unlocks new levels of memory density and efficiency, enabling revolutionary applications in AI, IoT, healthcare, and advanced computing. The low power consumption, simple architecture, and scalability of ReRAM make it well suited for next-generation electronic devices, shaping the future of computing and storage solutions. Disclosed implementations can provide improvements in ReRAM control, helping to enable one or more of the aforementioned applications.

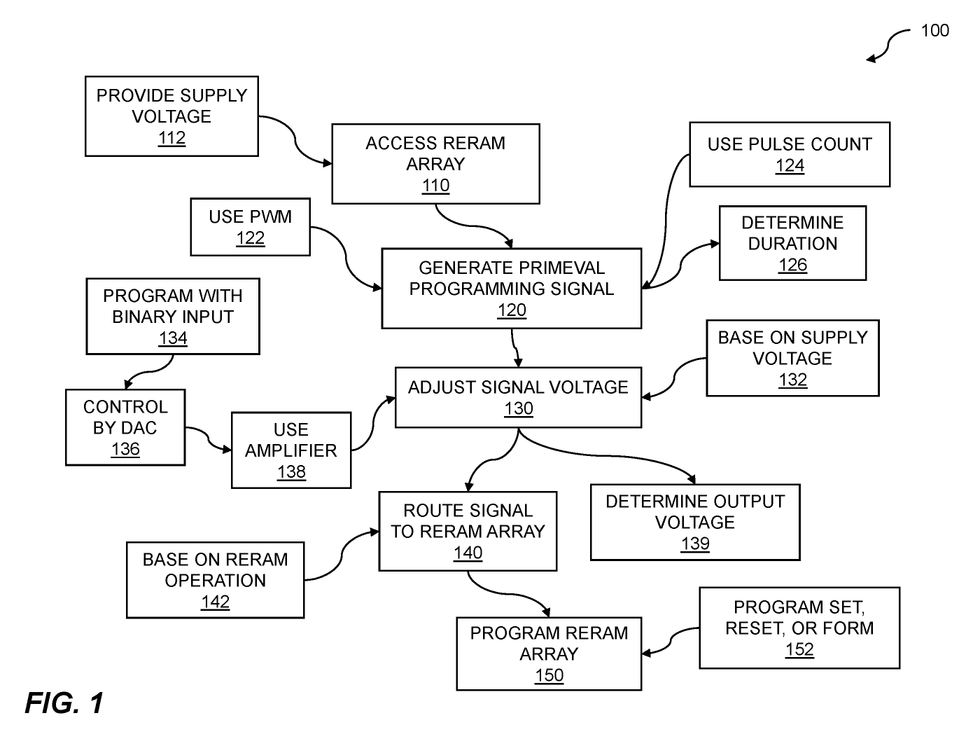

FIG. 1 is a flow diagram for dynamic control of resistive random-access memory. A resistive random-access memory (ReRAM) memory cell array is accessed. A variable pulse width primeval signal is generated using a pulse width modulator. The variable pulse width primeval signal is generated at an initial voltage, and a width of the variable pulse width primeval signal determines a duration of a variable pulse width programming signal. The initial voltage of the variable pulse width primeval signal is adjusted based on a binary digital input and a ReRAM memory cell array supply voltage, and the adjusting determines an output voltage of the variable pulse width programming signal. The variable pulse width programming signal is routed to a portion of the ReRAM memory cell array, based on a ReRAM operation, and the portion of the ReRAM memory cell array is programmed using the variable pulse width programming signal that was routed.

The flow 100 includes accessing a ReRAM array 110. The ReRAM array can include a filamentary array that utilizes a transition metal oxide, such as HfO₂, TiO₂, Ta₂O₅, and/or Al₂O₃. Embodiments can include accessing a resistive random-access memory (ReRAM) memory cell array. The flow 100 includes providing a supply voltage 112. In some implementations, the supply voltage can range from 2 volts to 6 volts. Other supply voltage ranges are possible in disclosed implementations. The flow 100 further includes generating a primeval programming signal 120. Thus, embodiments can include generating a variable pulse width primeval signal. The flow 100 includes using a pulse width modulator 122 in generation of the primeval programming signal. Thus, in embodiments, the variable pulse width primeval signal is generated using a pulse width modulator. The flow 100 includes using a pulse count 124. In disclosed implementations, a digital value that may be represented as an N-bit number is used for controlling the output of the pulse width modulator. In disclosed implementations, a higher value can correspond to a longer pulse width. In embodiments, the generating a variable pulse width programming signal is controlled by a pulse count input. The flow 100 includes determining a duration 126. Thus, in embodiments, a width of the variable pulse width primeval signal determines a duration of a variable pulse width programming signal.

The flow 100 includes adjusting a signal voltage 130. In embodiments, the adjusting includes adjusting the initial voltage of the variable pulse width primeval signal. The flow 100 includes basing the adjusted signal on the supply voltage 132. In disclosed implementations, the adjusted signal may be set to a voltage level that is less than the supply voltage. In some disclosed implementations, voltage boosting techniques may be used to set the voltage level of the adjusted signal to voltage that is greater than the supply voltage. In disclosed implementations, the voltage boosting techniques may include DC-DC boost converters, switched capacitor converters, transformer-based voltage converters, adjustable linear regulators with pre-boost, and/or other suitable techniques. The flow includes programming a voltage with a binary input 134. In embodiments, the initial voltage is adjusted based on a binary digital input and a ReRAM memory cell array supply voltage. The flow 100 includes control by a DAC (digital analog converter) 136. The DAC can include circuitry and/or logic to convert digital values specified in binary, or BCD, into corresponding analog voltages. In disclosed implementations, the DAC can include a resistor string DAC, R-2R ladder DAC, current-steering DAC, or other suitable type of DAC. The flow 100 can further include using an amplifier 138. In disclosed implementations, the amplifier can be controlled by the output of the DAC. In embodiments, adjusting an initial voltage of the variable pulse width programming signal is performed by a voltage amplifier. The amplifier can include a class D amplifier, MOSFET-based switching amplifier, and/or other suitable type of amplifier. Moreover, in embodiments, the voltage amplifier is controlled by a digital-to-analog converter (DAC). The flow 100 includes determining the output voltage 139. In embodiments, the binary digital input determines the output voltage. In embodiments, the binary digital input is converted to an analog voltage to effect the controlling of the voltage amplifier.

The flow 100 includes routing a signal to the ReRAM array 140. Embodiments can include routing the variable pulse width programming signal to a portion of the ReRAM memory cell array, based on a ReRAM operation. The flow 100 includes basing the routing on a ReRAM operation 142. The ReRAM operation can include a programming operation, such as a SET operation, RESET operation, and/or other types of operations. The routing can include manipulating a variety of control signals, such as a wordline, bitline, select line; and/or operational control signals such as a write enable signal, read enable signal, set signal, and/or reset signal. In embodiments, routing the variable pulse width programming signal enables control of a ReRAM memory cell array wordline, a ReRAM memory cell array bitline, and a ReRAM memory cell array select line.

The flow 100 includes programming the ReRAM array 150. Embodiments include programming the portion of the ReRAM memory cell array, using the variable pulse width programming signal that was routed. The programming can include writing data to one or more memory locations (addresses) within the ReRAM memory cell array. The flow 100 can further include programming a set, reset, and/or form operation 152. In disclosed implementations, a reset operation includes applying a voltage to dissolve filaments, returning the material to its high-resistance state (HRS). In disclosed implementations, a set operation includes applying a voltage to create filaments, setting the material to its low-resistance state (LRS). In disclosed implementations, the form operation includes applying voltages to create conductive paths (filaments) within the resistive switching material of the ReRAM memory cell array.

Various steps in the flow 100 may be changed in order, repeated, omitted, or the like without departing from the disclosed concepts. Various embodiments of the flow 100 can be included in a computer program product embodied in a non-transitory computer readable medium that includes code executable by one or more processors. Various embodiments of the flow 100, or portions thereof, can be included on a semiconductor chip and implemented in special purpose logic, programmable logic, and so on.

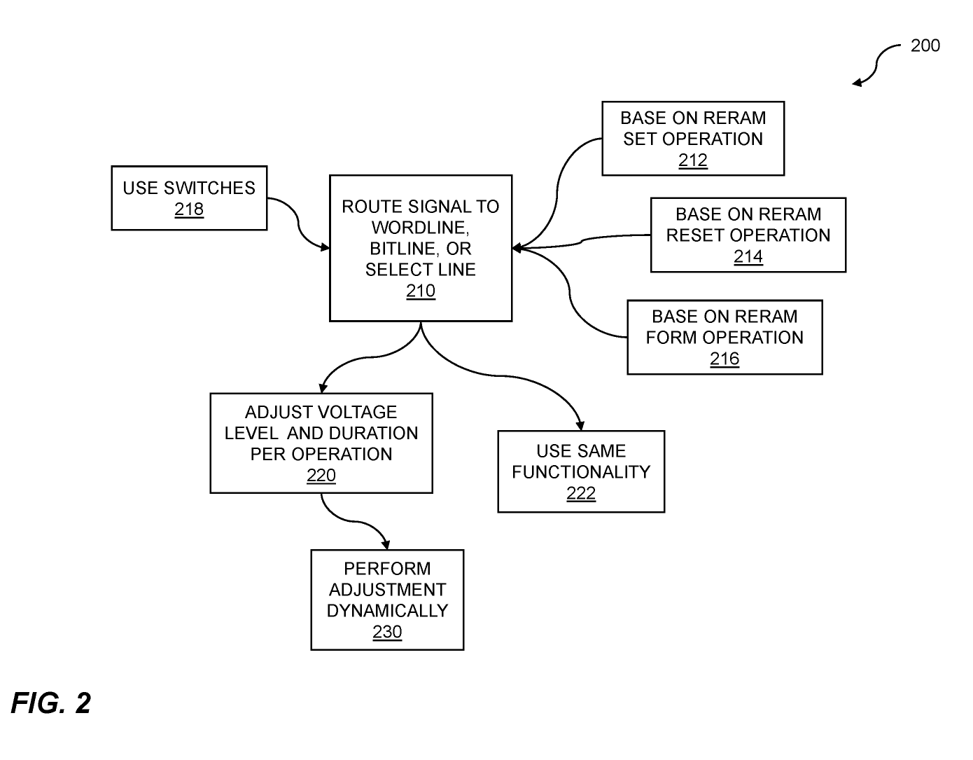

FIG. 2 is a flow diagram for resistive random-access memory operations. The operations can include set operations, reset operations, form operations, and/or other ReRAM memory operations. The operations can include changing the resistive state of one or more portions of a ReRAM memory cell array via programming of corresponding components to generate appropriate voltages on one or more control signals and/or operational control signals of the ReRAM memory cell array. A resistive random-access memory (ReRAM) memory cell array is accessed. A variable pulse width primeval signal is generated using a pulse width modulator. The variable pulse width primeval signal is generated at an initial voltage, and a width of the variable pulse width primeval signal determines a duration of a variable pulse width programming signal. The initial voltage of the variable pulse width primeval signal is adjusted based on a binary digital input and a ReRAM memory cell array supply voltage, and the adjusting determines an output voltage of the variable pulse width programming signal. The variable pulse width programming signal is routed to a portion of the ReRAM memory cell array, based on a ReRAM operation, and the portion of the ReRAM memory cell array is programmed using the variable pulse width programming signal that was routed.

The flow 200 includes routing a signal to a wordline, bitline, or select line 210. In a ReRAM (Resistive RAM) memory cell array, the word line (WL), bit line (BL), and select line (SL) are array design features that work together to prepare, access, and control memory cells for read and write operations. The wordline (WL) can enable activation of a specific row in the ReRAM memory cell array. The wordline can be controlled by a row decoder that selects the correct row based on a specified memory address. The selected WL enables voltage signals to be applied to all memory cells in that row. Similarly, the bitline (BL) can enable access of a specific column in the array. The bitline can be controlled by a column decoder, which selects the appropriate column based on the specified memory address. The select line (SL) can be used to complete the electrical circuit during read and write operations. In some implementations, the select line may be tied to ground for a simple 1T1R (one-transistor-one-ReRAM) configuration. In some implementations, during a write operation, the source line voltage can be adjusted along with the bitline to provide the correct voltage differential across the ReRAM memory cell.

The flow 200 includes using the same functionality 222. In disclosed implementations, similar circuitry and/or logic may be used to control bitlines, wordlines, and select lines. In embodiments, control of the ReRAM memory cell array wordline, the ReRAM memory cell array bitline, and the ReRAM memory cell array select line is managed by logic blocks comprising the same generating, adjusting, and routing functionality.

The flow 200 includes basing the routing on a ReRAM set operation 212. In exemplary implementations, the set operation can be used for a write operation at a specified memory location. The flow 200 includes basing the routing on a ReRAM reset operation 214. In exemplary implementations, the reset operation can be used before write or read operations at a specified memory location. The flow 200 includes basing the routing on a ReRAM form operation 216. In exemplary implementations, the form operation can be used to initialize a new ReRAM memory cell array by creating the filaments used for resistive switching control. The flow 200 includes using switches 218. The switches can include pass device switches. One or more transistors can be used as pass device switches to control the flow of electrical signals or power between different circuit elements in the ReRAM memory controllers of disclosed implementations. As a pass switch, a transistor can be configured to operate as a controllable connection, allowing or blocking current based on an input control signal. In embodiments, the routing the variable pulse width programming signal is gated to the portion of the ReRAM memory cell array being programmed using one or more pass device switches.

The flow 200 includes adjusting the voltage level and duration per operation 220. The operation can include a set operation, reset operation, form operation, and/or other types of ReRAM memory cell operations. The flow 200 includes performing the adjustment dynamically 230. Thus, in embodiments, the generating, the adjusting, and the routing are determined dynamically on a per programming operation basis. The required voltages for setting and resetting ReRAM memory cells can change slightly over time due to several factors, including device aging and operating temperature variations. These factors can affect the physical properties of the ReRAM materials and their switching characteristics. For example, over many program/erase (set/reset) cycles, the conductive filaments in the switching layer of ReRAM can degrade or become more difficult to form or rupture. Moreover, higher operating temperatures can influence ion mobility and filament formation, making set/reset operations more variable. Additionally, some ReRAM materials can exhibit a temperature-dependent threshold voltage shift. By performing the adjustment of the voltage level and/or duration dynamically, disclosed implementations can accommodate changing characteristics of a ReRAM cell. Disclosed implementations may utilize adaptive write voltage control to dynamically adjust the applied voltages based on feedback from read operations. Some implementations may utilize error correction codes (ECC) to compensate for minor drifts in voltages. Some implementations may utilize endurance management techniques that perform wear leveling to distribute writes to reduce localized degradation. The dynamic adjustment of applied voltages of disclosed implementations can serve to reduce access errors and improve overall performance with ReRAM cells. In embodiments, the per programming operation basis corresponds to a ReRAM set operation, a ReRAM reset operation, or a ReRAM form operation.

Various steps in the flow 200 may be changed in order, repeated, omitted, or the like without departing from the disclosed concepts. Various embodiments of the flow 200 can be included in a computer program product embodied in a non-transitory computer readable medium that includes code executable by one or more processors. Various embodiments of the flow 200, or portions thereof, can be included on a semiconductor chip and implemented in special purpose logic, programmable logic, and so on.

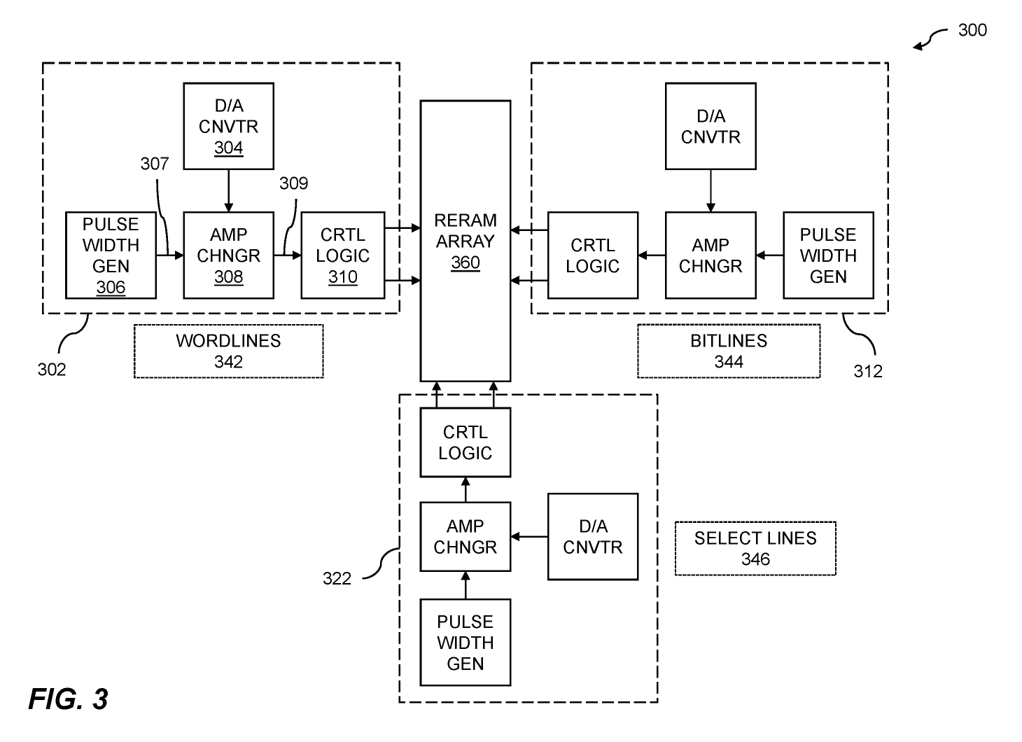

FIG. 3 is a block diagram for dynamic control of resistive random-access memory. A resistive random-access memory (ReRAM) memory cell array is accessed. A variable pulse width primeval signal is generated using a pulse width modulator. The variable pulse width primeval signal is generated at an initial voltage, and a width of the variable pulse width primeval signal determines a duration of a variable pulse width programming signal. The initial voltage of the variable pulse width primeval signal is adjusted based on a binary digital input and a ReRAM memory cell array supply voltage, and the adjusting determines an output voltage of the variable pulse width programming signal. The variable pulse width programming signal is routed to a portion of the ReRAM memory cell array, based on a ReRAM operation, and the portion of the ReRAM memory cell array is programmed using the variable pulse width programming signal that was routed. Thus, the selected operation (e.g., set, reset, form, etc.) is routed to the selected array design feature (e.g., wordline, bitline, select line, etc.) to provide the appropriate variable pulse width, adjusted voltage programming signal.

The block diagram 300 includes three similar dynamic control blocks, indicated at 302, 312, and 322. Control block 302 controls wordlines 342. Control block 312 controls bitlines 344. Control block 322 controls select lines 346. Referring now to control block 302, it includes a pulse width generator 306 that outputs a signal of a specified duration, referred to as a primeval signal 307. Depending on the ReRAM operation (e.g., set, reset, form, etc.), the amplitude of the primeval signal 307 is adjusted based on a value programed into digital analog converter 304. The output of the digital analog converter 304 is input to the amplitude changer 308 as a control signal to control the amount of amplitude change in the output filtered signal 309. The filtered signal 309 is an amplitude changed version of the primeval signal 307. The filtered signal 309 is input to control logic 310, which in turn controls the wordline of ReRAM array 360. The control blocks 312 and 322 operate in a similar manner to control block 302 and can include similar components as control block 302.

The block diagram 300 can comprise an apparatus for memory operation control comprising: a resistive random-access memory (ReRAM) memory cell array, wherein the ReRAM array comprises wordlines, bitlines, and select lines; a first control logic coupled to the wordlines of the ReRAM array, wherein the first control logic drives the wordlines of the ReRAM array, based on a first selection input; a second control logic coupled to the bitlines of the ReRAM array, wherein the second control logic drives the bitlines of the ReRAM array, based on a second selection input; a third control logic coupled to the select lines of the ReRAM array, wherein the third control logic drives the select lines of the ReRAM array, based on a third selection input; and input decoding logic coupled to the first control logic, the second control logic, and the third control logic, wherein the input decoding logic enables ReRAM operation selection, and wherein an operation that was selected is performed with a variable pulse width, adjusted voltage programming signal.

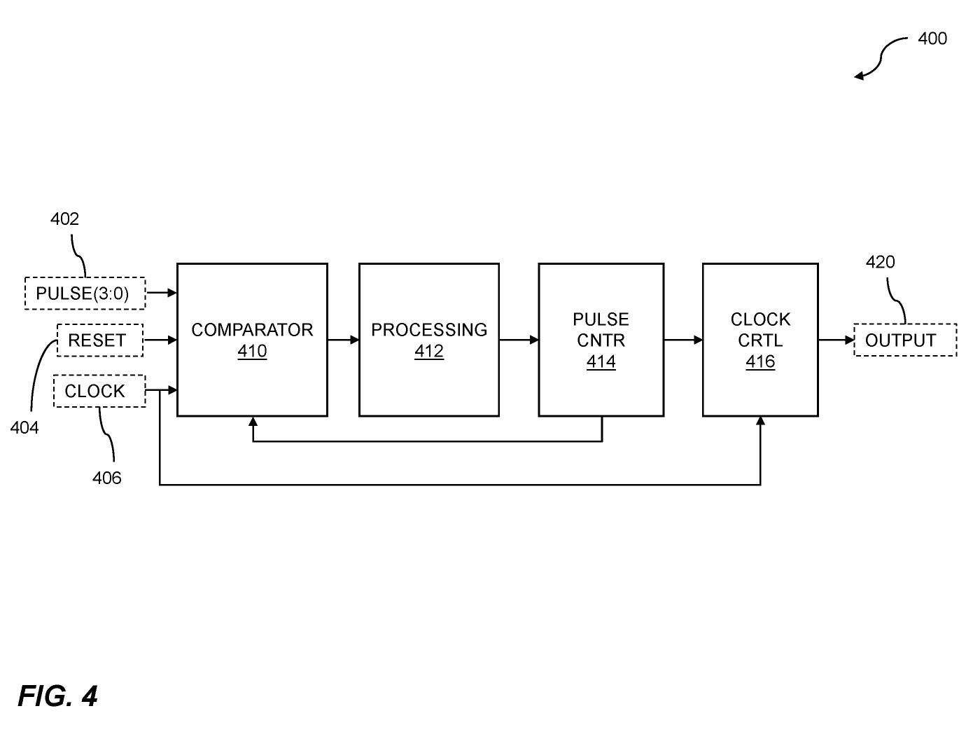

FIG. 4 is a block diagram for resistive random access memory pulse width generation. A resistive random-access memory (ReRAM) memory cell in the array is accessed using control logic. A variable pulse width primeval signal is generated using a pulse width modulator. The variable pulse width primeval signal is generated at an initial voltage, and a width of the variable pulse width primeval signal determines a duration of a variable pulse width programming signal. The initial voltage of the variable pulse width primeval signal is adjusted based on a binary digital input and a ReRAM memory cell array supply voltage, and the adjusting determines an output voltage of the variable pulse width programming signal. The variable pulse width programming signal is routed to a portion of the ReRAM memory cell array, based on a ReRAM operation, and the portion of the ReRAM memory cell array is programmed using the variable pulse width programming signal that was routed.

The block diagram 400 includes a binary input 402. In disclosed implementations, the binary input 402 can include a four-bit input that specifies the width/duration of an output pulse. In embodiments, the pulse count input comprises a 4-bit binary input. The binary input 402 can be used to define the pulse count dynamically during operations. The block diagram 400 can further include a reset signal 404 that initializes or resets the internal registers and counters and ensures (by cycling the reset signal) that the system starts cleanly before generating a new pulse sequence. The block diagram 400 can further include a clock 406 that serves as the timing reference for pulse generation and drives the counters, enabling synchronization with other system components. The binary input 402, reset signal 404, and clock 406 are input to a comparator 410. The comparator 410 can include a digital circuit that compares two binary values and determines their relationship as to whether they are equal, greater than, or less than. In disclosed implementations, the comparator 410 comprises a multi-bit comparator. In some implementations, the multi-bit comparator may be implemented as multiple cascaded 1-bit comparators. The comparator 410 can compare the current pulse count with the desired number of pulses to determine when to stop generating pulses. The output of the comparator 410 is input to a processing block 412. The processing block 412 can include circuitry and logic to decode input signals and control the state of the PWM generator. The processing block 412 can implement state transitions using a finite-state machine (FSM). The states within the FSM can include a START state that activates the pulse generation process. The states within the FSM can further include a STAY state that remains idle when no pulse is requested. The output of the processing block 412 can be input to the pulse counter 414. The pulse counter 414 can include circuitry and logic to track the number of pulses generated.

In disclosed embodiments, a pulse count is incremented on each clock cycle when the system is in a START state, and is reset to zero when the comparator indicates that the desired pulse count has been reached. The output of the pulse counter 414 can be provided to the clock cycle control block 416. In disclosed implementations, the clock cycle control block 416 manages the timing of pulses and synchronizes pulse generation with the clock 406 for accurate timing. The output of the clock cycle control block 416 is output signal 420 which can be a modulated signal generated by combining the clock signal with the state of the pulse counter, and can be used for controlling ReRAM operations. In disclosed implementations, the output signal 420 can serve as the primeval signal. The output signal 420 can have pulses of variable width. In embodiments, the pulse count input generates a variable pulse width programming signal having a duration in the range of 0.2ns (nanoseconds) to 10ms (milliseconds).

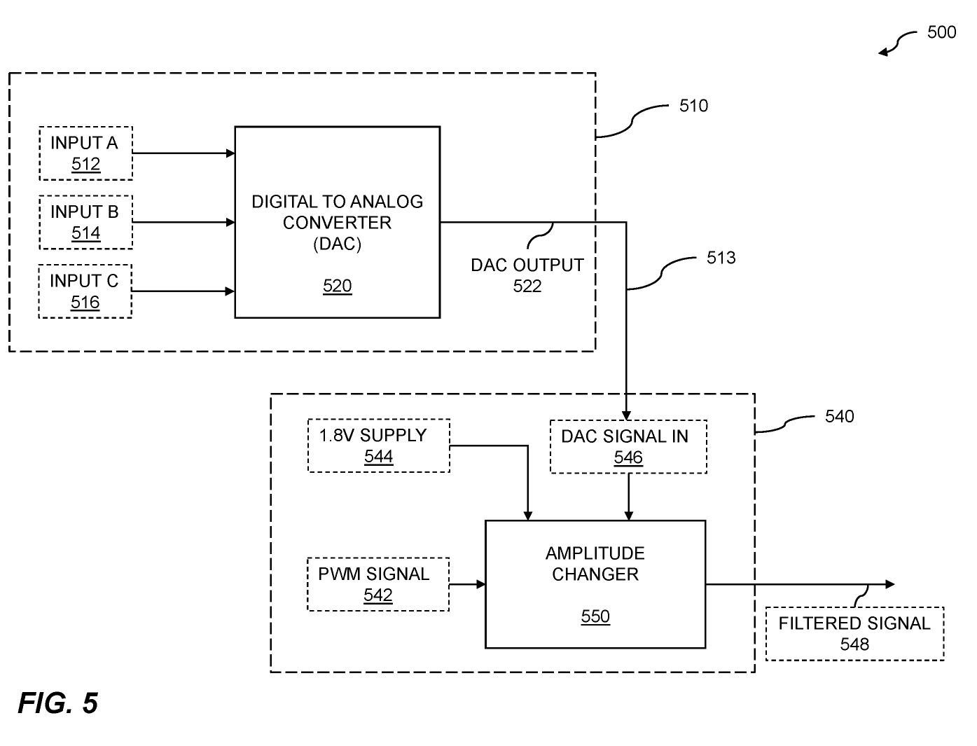

FIG. 5 is a block diagram for resistive random access memory amplitude adjusting using a DAC. Memory amplitude adjusting can enable dynamic control of ReRAM. A resistive random-access memory (ReRAM) memory cell array is accessed. A variable pulse width primeval signal is generated using a pulse width modulator. The variable pulse width primeval signal is generated at an initial voltage, and a width of the variable pulse width primeval signal determines a duration of a variable pulse width programming signal. The initial voltage of the variable pulse width primeval signal is adjusted based on a binary digital input and a ReRAM memory cell array supply voltage, and the adjusting determines an output voltage of the variable pulse width programming signal. The variable pulse width programming signal is routed to a portion of the ReRAM memory cell array, based on a ReRAM operation, and the portion of the ReRAM memory cell array is programmed using the variable pulse width programming signal that was routed.

The block diagram 500 includes amplitude changer control (ACC) module 510. The ACC module 510 is a component that enables generation of precise voltage levels that can be utilized for various ReRAM operations, such as set, reset, and form. The functions of ACC module 510 include converting digital control signals into analog voltage levels, enabling fine-grained control over the ReRAM array. ACC module 510 can include multiple binary digital input signals, indicated as A 512, B 514, and C 516. The binary digital input signals can be used as input to digital analog converter (DAC) 520. In exemplary implementations, the DAC 520 utilizes a resistor ladder structure to scale the reference voltage based on the binary inputs. The resistors can divide the reference voltage into smaller increments, corresponding to the weights of the binary input bits. In embodiments, the DAC is programmed by a binary digital input. In embodiments, the binary digital input comprises 3 bits. The output 522 of the DAC serves as an amplitude changer control signal 513. The amplitude changer control signal 513 can be an analog signal, where the voltage level of the analog signal is based on the binary digital input that is input to DAC 520.

The block diagram 500 further includes an amplitude changer module 540. The amplitude changer module 540 component includes circuitry and/or logic that can adjust the voltage levels of the output signal dynamically. The amplitude changer module 540 enables the ReRAM to receive the appropriate signal amplitude for different operations such as set, reset, and form. The amplitude changer module 540 integrates inputs from the PWM, DAC, and control logic to generate a filtered output signal optimized for ReRAM programming. The amplitude changer module 540 includes a DAC signal input 546 that receives the amplitude changer control signal 513. Within the amplitude changer module 540, an output of the PWM signal generator 542, which may be similar to block diagram 400 of FIG. 4, is input to amplitude changer 550, which is powered by supply voltage 544. The amplitude changer 550 can include one or more voltage amplifiers and/or inverters. The voltage amplifiers can serve to amplify the input PWM signal based on the DAC output. It can enable the amplitude of the PWM-modulated signal to be aligned with the operational requirements of ReRAM. The inverters can utilize the 1.8V input and DAC supply to dynamically switch between high and low states, generating the desired amplitude signal.

The output of the PWM signal generator 542 can provide the timing for ReRAM operations. The output of the PWM signal generator 542 can serve as the base waveform to be amplified. In disclosed implementations, supply voltage 544 can include a 1.8-volt supply. The supply voltage 544 can include a direct current (DC) supply voltage. The supply voltage 544 can serve as a secondary power source for initial signal stages and can enable compatibility with control logic operating at lower voltage levels. The output of amplitude changer 550 is filtered signal 548. The filtered signal 548 is of the appropriate duration and voltage level to support a given ReRAM memory operation. Thus, the filtered signal 548 can be based on a combination of the PWM timing and the DAC-modulated amplitude, and can be fine-tuned to meet the voltage and timing specifications required for ReRAM operations.

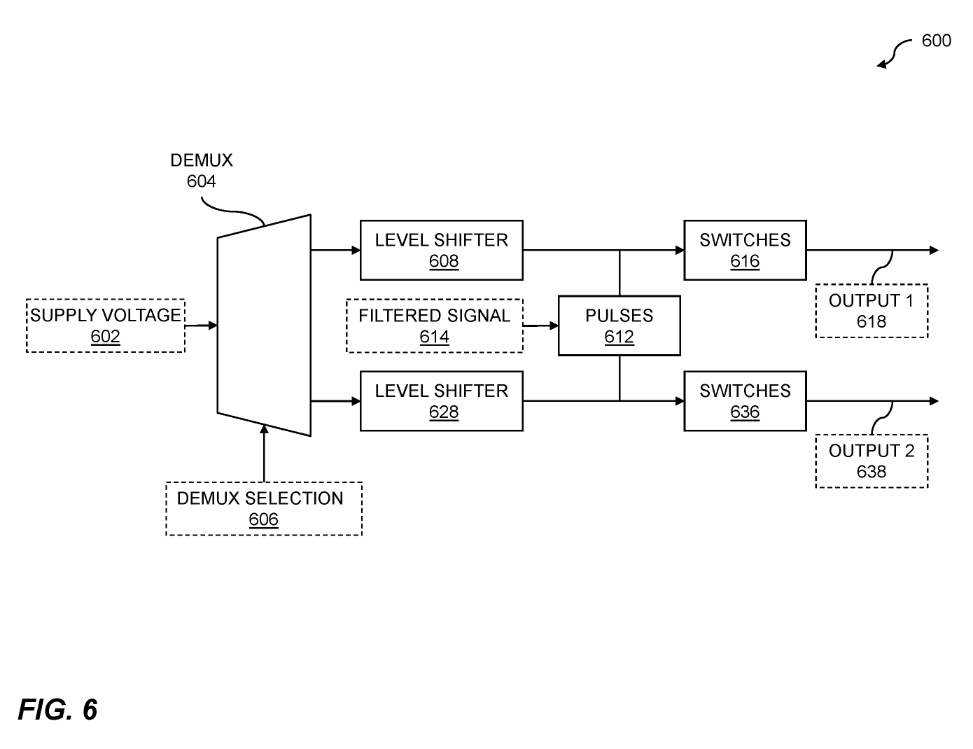

FIG. 6 is a block diagram for resistive random access memory routing control. Memory routing control can enable dynamic control of ReRAM. A resistive random-access memory (ReRAM) memory cell array is accessed. A variable pulse width primeval signal is generated using a pulse width modulator. The variable pulse width primeval signal is generated at an initial voltage, and a width of the variable pulse width primeval signal determines a duration of a variable pulse width programming signal. The initial voltage of the variable pulse width primeval signal is adjusted based on a binary digital input and a ReRAM memory cell array supply voltage, and the adjusting determines an output voltage of the variable pulse width programming signal. The variable pulse width programming signal is routed to a portion of the ReRAM memory cell array, based on a ReRAM operation, and the portion of the ReRAM memory cell array is programmed using the variable pulse width programming signal that was routed.

The block diagram 600 shows the filtered signal from the amplitude changer being directed to specific ReRAM wordlines, bitlines, or select lines. The block diagram 600 can utilize a DEMUX for selection, level shifters for voltage adaptation, and/or switches to gate the filtered signal to specific output lines. The inputs to block diagram 600 include a filtered signal 614, as previously described. The filtered signal 614 can provide pulse-timed pulses 612, and also amplitude-adjusted as needed for programming (set, reset, form) and/or reading operations. In embodiments, the ReRAM set operation provides a variable pulse width programming signal voltage of 2V+/-10%. In embodiments, the ReRAM reset operation provides a variable pulse width programming signal voltage of 3.3V+/-10%. In embodiments, the ReRAM form operation provides a variable pulse width programming signal voltage of 4.3V+/-10%. In embodiments, a ReRAM programming operation signal voltage is greater than a supply voltage for the ReRAM memory cell array.

The inputs to block diagram 600 can further include a selection input 606, which is a digital signal input to the DEMUX 604, determining which output line (e.g., output 1618, or output 2638) is selected. The inputs to block diagram 600 can further include power supply voltage 602. In disclosed implementations, the power supply voltage 602 can be a 1.8-volt DC voltage. Other voltages are possible in disclosed implementations. The output of power supply voltage 602 can be directed to level shifter 608 and/or level shifter 628 via DEMUX 604. The level shifters (608, 628) can be configured to convert control signals from 1.8V to the higher operating voltages required for switches and ReRAM array operations. Control signals can pass through level shifters (608, 628) to ensure that the signals meet the voltage requirements of the switches (616, 636). While the filtered signal 614 from the amplitude changer is directly connected to all switches, only the switch corresponding to the active DEMUX output allows the filtered signal to pass to the output line. The selection input 606 is fed to the DEMUX 604, which generates control signals to activate specific switches, indicated as 616 and 636. In disclosed implementations, switch 616 and switch 636 can be pass switch devices. In embodiments, the routing the variable pulse width programming signal is gated to the portion of the ReRAM memory cell array being programmed using one or more pass device switches. The two outputs (i.e., output 1618 and output 2638) can be used to selectively drive a first row or a second row, or a first column or a second column. The DEMUX selection criteria is thus whether the signal should be driven to the first output or the second output of a “2 x 2” array.

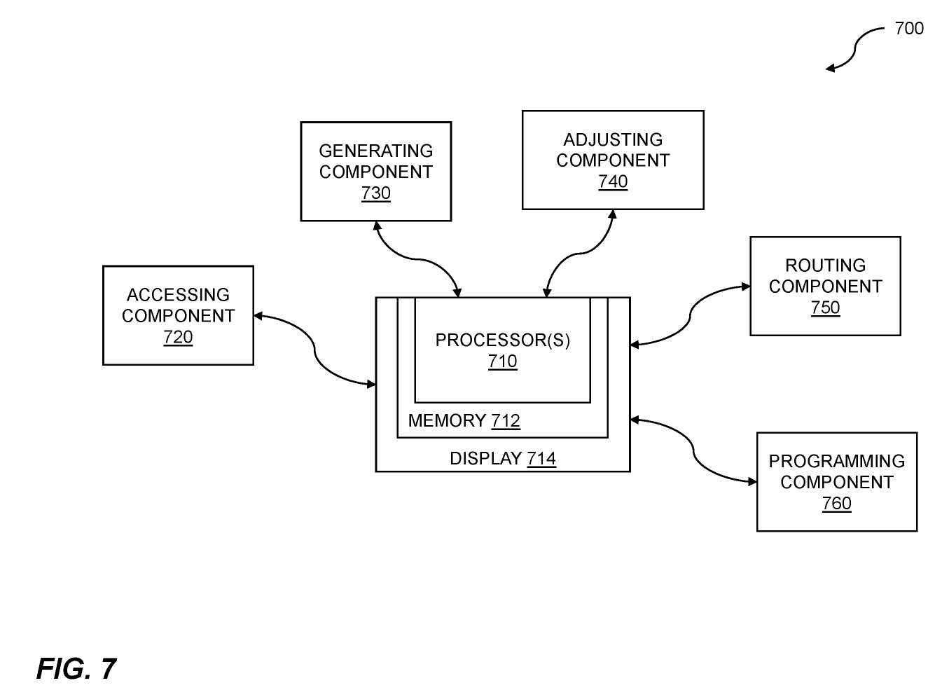

FIG. 7 is a system diagram for dynamic control of resistive random-access memory. The dynamic control of resistive random-access memory can be enabled using PWM signals that are amplitude controlled based on binary digital inputs. The system 700 includes one or more processors 710, which are coupled to a memory 712 that stores instructions. The system 700 can further include a display 714 coupled to the one or more processors 710 for displaying data, such as ReRAM memory cell configuration parameters. The configuration parameters can include voltage levels, pulse durations, binary values, and so on. The displayed data can further include information derived from a database of ReRAM memory cell array parameters, including operating parameters such as voltage levels, programming constraints, and so on. In embodiments, one or more processors 710 are coupled to the memory 712, wherein the one or more processors, when executing the instructions which are stored, are configured to: access a resistive random-access memory (ReRAM) memory cell array; generate a variable pulse width primeval signal, wherein the variable pulse width primeval signal is generated using a pulse width modulator, wherein the variable pulse width primeval signal is generated at an initial voltage, and wherein a width of the variable pulse width primeval signal determines a duration of a variable pulse width programming signal; adjust the initial voltage of the variable pulse width primeval signal, wherein the initial voltage is adjusted based on a binary digital input and a ReRAM memory cell array supply voltage, and wherein the adjusting determines an output voltage of the variable pulse width programming signal; route the variable pulse width programming signal to a portion of the ReRAM memory cell array, based on a ReRAM operation; and program the portion of the ReRAM memory cell array, using the variable pulse width programming signal that was routed.

The system 700 includes an accessing component 720. The accessing component 720 can include functions and instructions to enable access to a resistive random-access memory (ReRAM) memory cell array. The resistive random-access memory (ReRAM) memory cell array can include one or more input signals, such as wordline signals, bitline signals, select signals, set signals, reset signals, and so on. The ReRAM cell array can be in a consumer electronic device such as a smartphone, laptop, streaming device, or the like. In those types of consumer electronic devices, ReRAM can replace or supplement flash memory for faster, more energy-efficient data storage. The ReRAM cell array can be in an embedded system such as an IoT device, or wearable device, medical device (e.g., pacemaker, hearing aid), where the features of reliable memory storage with low power consumption provide important benefits. Other types of devices may also benefit from the advantages provided by ReRAM technology. The system 700 includes a generating component 730. The generating component 730 can include functions and instructions to enable generation of a variable pulse width primeval signal, where the variable pulse width primeval signal is generated using a pulse width modulator (PWM). The PWM can provide precise timing and frequency control integrated into the control logic, and may utilize external clocks for synchronization in order to achieve real-time adaptability.

The system 700 includes an adjusting component 740. The adjusting component 740 can include functions and instructions to enable adjusting of the initial voltage of the variable pulse width primeval signal, where the initial voltage is adjusted based on a binary digital input and a ReRAM memory cell array supply voltage. In some exemplary implementations, the adjustments can include adjusting voltage levels, pulse durations, and/or other signal parameters. In some cases, the adjusted voltage may be higher than a supply voltage. Disclosed implementations may utilize a switching regulator such as a step-up (boost) or buck-boost converter, linear voltage regulator, charge pump, and/or other suitable techniques. The system 700 includes a routing component 750. The routing component 750 can include functions and instructions to enable routing of the variable pulse width programming signal to a portion of the ReRAM memory cell array, based on a ReRAM operation. The routing can utilize the wordline and bitline subsystems to manage the horizontal and vertical addressing of the ReRAM cells. These lines can receive control signals to ensure precise targeting of specific memory cells during operations like read and write. These subsystems may be used in conjunction with the select line subsystem to provide an additional layer of routing control. The programming signal can enable a ReRAM memory cell array programming operation, such as a set operation, a reset operation, a form operation, and/or other ReRAM memory cell array programming operations as supported by a particular ReRAM memory cell array device.

The system 700 includes a programming component 760. The programming component 760 can include functions and instructions to enable programming the portion of the ReRAM memory cell array, using the variable pulse width programming signal that was routed. The programming can include updating one or more memory locations with updated data, performing a FORM operation, and/or implementing other suitable programming operations as supported by a particular ReRAM memory cell array device. The programming can be performed dynamically. The dynamic programming techniques provided by disclosed implementations can play an important role in enhancing the reliability, endurance, and efficiency of Resistive RAM (ReRAM) by adapting set and reset operations based on real-time feedback. Unlike traditional fixed-voltage programming, disclosed implementations can provide adaptive pulse control to ensure that memory cells are successfully programmed while minimizing stress and power consumption. ReRAM cells may exhibit variability due to manufacturing differences, aging effects, and/or temperature fluctuations. A one-size-fits-all voltage or pulse width may not always lead to a successful set (low-resistance state) or reset (high-resistance state) operation. Disclosed implementations can provide dynamic programming techniques that allow the memory controller to verify each operation and, if needed, adjust the voltage level or pulse duration dynamically. For example, if a set operation does not successfully form the conductive filament, a slightly higher voltage or longer pulse width can be applied on a subsequent attempt. Similarly, if a reset operation does not fully disrupt the filament, a modified pulse shape can be applied to ensure proper resistance switching. The modified pulse shape can include increasing the duration (width) of the pulse.

The system 700 can include a computer system for memory control comprising: a memory which stores instructions; one or more processors coupled to the memory, wherein the one or more processors, when executing the instructions which are stored, are configured to: access a resistive random-access memory (ReRAM) memory cell array; generate a variable pulse width primeval signal, wherein the variable pulse width primeval signal is generated using a pulse width modulator, wherein the variable pulse width primeval signal is generated at an initial voltage, and wherein a width of the variable pulse width primeval signal determines a duration of a variable pulse width programming signal; adjust the initial voltage of the variable pulse width primeval signal, wherein the initial voltage is adjusted based on a binary digital input and a ReRAM memory cell array supply voltage, and wherein the adjusting determines an output voltage of the variable pulse width programming signal; route the variable pulse width programming signal to a portion of the ReRAM memory cell array, based on a ReRAM operation; and program the portion of the ReRAM memory cell array, using the variable pulse width programming signal that was routed.

Another issue that can occur with memory devices is one of endurance. Applying excessive voltage or pulse durations increases power consumption and accelerates device wear over time. Disclosed implementations can provide dynamic programming techniques that help optimize the energy required for each memory cell by applying the minimal necessary pulse energy while still ensuring a successful write. This can reduce unnecessary electrical stress on the memory cells, which can extend the lifespan of a ReRAM device. Another issue that can occur with memory devices is variation across manufacturers and/or fabrication batches. The variation can result in devices that have slightly different switching characteristics. Disclosed implementations can provide dynamic programming techniques that enable automatic calibration to different ReRAM characteristics, allowing manufacturers to source ReRAM from multiple suppliers without significant redesigns. This can improve overall manufacturing yield and flexibility by accommodating process variations in ReRAM cells.

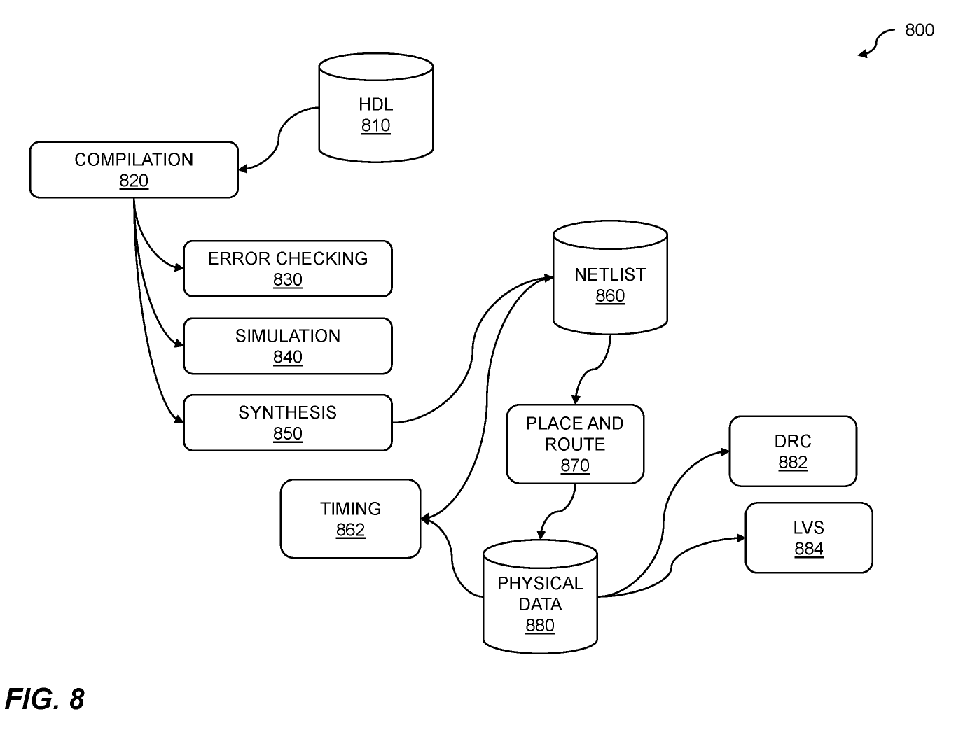

FIG. 8 is a design flow for semiconductor logic generation. Semiconductor logic generation can enable dynamic control of resistive random-access memory. The design flow can be based on one or more design automation tools and can include instructions and/or functions for design, generation of semiconductor logic for, and implementation of integrated circuits that support non-flushing vector micro-operations with VSET. The design flow 800 can include instructions and/or functions for generation and/or manipulation of design data such as hardware description language (HDL) constructs for specifying structure and operation of an integrated circuit. The design flow 800 can further perform operations to generate and manipulate Register Level Transfer (RTL) abstractions. These abstractions can include parameterized inputs that enable specifying elements of a design such as a number of elements, sizes of various bit fields, sizes of caches, number of registers, enablement of certain features (such as architectural extensions), and so on. The parameterized inputs can be used as inputs to a logic synthesis process which can create semiconductor logic that implements the gate-level abstraction of the HDL. The gate level data can be further processed and used for fabrication of integrated circuit (IC) devices.

Modern integrated circuit designs are typically created using complex software design automation tools. The design flow 800 includes a hardware description language (HDL) 810 of a logic design. The HDL can enable a human to create and test a description of a logic function, logic block, system, etc. they want to design by describing the system using code. Any HDL can be used including Verilog^{®}, VHDL, SystemC, Chisel, and other languages. The code can describe the system at various levels of abstraction. The levels of abstraction can include a high level of abstraction that describes the behavior of the system, at a register transfer level (RTL), which describes the design based on the transfer of data between registers, at a gate level description, which names the particular circuits used and the interconnections between them, and so on. For example, a high level behavioral description may describe multiplication as C = A * B. An RTL level may describe loading data into register A, loading data into register B, performing a multiplication operation, and storing the product of A and B in register C. A circuit level description may name the particular circuits to use and the interconnections among them. At the RTL stage, disclosed implementations can capture both functional behavior and timing relationships. While the behavioral description can be the most user friendly, the RTL description can enable more control over how the design is implemented. Common text file formats, such as “.v”, “.vhd”, are typically used for the HDL source code in the semiconductor design flow.

The HDL source code can be compiled 820. The compilation can comprise one or more analysis, parsing, and/or elaboration steps. The compilation can result in an executable model of the HDL source code, which can be suitable for further steps of design automation. The executable model can be hierarchical. The compilation process can include error checking 830. The error checking can include syntactical checking; semantic checking; checking of references to other referenced libraries, designs, and models; etc. One or more implementations may include automated linting tools that detect undeclared signals, mismatched bit widths, or unused variables in HDL code.

One or more implementations may include simulation 840 of the HDL or RTL code prior to synthesis. Simulation environments can enable verification of design parameters such as functional correctness, timing behavior, and corner cases. By running testbenches against the HDL code, designers can confirm that arbitration logic operates as intended before committing to gate level synthesis. Simulation can also provide visibility into signal waveforms and processor request interactions, ensuring that arbitration criteria are correctly enforced. One or more implementations may also address conflicts that arise in visualization and reporting. For example, waveform viewers and schematic generators may use color coding to distinguish signals, buses, and states. Conflicts in color assignments or overlapping graphical elements can obscure analysis. Tools therefore include configurable color palettes and conflict resolution mechanisms to ensure clarity in simulation results and design documentation.

Synthesis 850 tools can be used to map the abstract operations captured by the HDL code into logic gates, flip-flops, cache structures, interconnect structures, etc. This process can enable automated generation of semiconductor logic that can be implemented in silicon, while preserving the intended arbitration and control functions originally specified. The synthesis can produce a gate level netlist 860 that represents the actual semiconductor logic structures such as described above. The netlist can be a technology-mapped netlist (e.g., mapped to a specific semiconductor fabrication technology). Synthesized netlists may be represented in formats such as EDIF, Liberty, and so on. In some implementations, checking can be performed to ensure that the logic generated by the synthesis tool is equivalent to the logic defined by the HDL source code. This can be accomplished by one or more testbenches, running one or more tests on larger blocks of logic and comparing those to the synthesized circuits, performing formal verification to prove logical equivalence between HDL and the netlist, and so on. Timing 862 can be performed on the netlist. The timing can generate an initial view including critical paths and/or paths that should be retimed with different synthesis directions. The timing information can be generated from established models of semiconductor devices, gates, etc. that have been selected by the synthesis tool. Estimates for wiring delays can also be included in the timing data.

The gate level netlist can be placed and routed 870 to produce physical data 880 which represents layout suitable for fabrication. Examples of place and route tools are Cadence^{®} Innovus^{®}, Synopsis IC complier^{®}, versatile place and route (VPR), nextpnr, and others. Layout data is often exchanged in GDSII or OASIS formats. These standardized formats enable interoperability across tools and vendors, and support error checking during import/export. Timing 862 can again be run on the placed and routed design to ensure that the design meets cycle time requirements, taking into account more accurate wire lengths, parasitics, clock domains, and so on. Design rule checks (DRC) 882 and layout versus schematic (LVS) 884 checks can confirm that the generated semiconductor logic adheres to fabrication constraints and matches the intended design. This tool-based flow demonstrates how software code can be transformed into concrete semiconductor logic structures, providing enabling support for claims directed to logic generation.

The design flow 800 can implement a computer program product embodied in a non-transitory computer readable medium for machine learning processing, the computer program product comprising code which causes one or more processors to generate semiconductor logic for: accessing a resistive random-access memory (ReRAM) memory cell array; generating a variable pulse width primeval signal, wherein the variable pulse width primeval signal is generated using a pulse width modulator, wherein the variable pulse width primeval signal is generated at an initial voltage, and wherein a width of the variable pulse width primeval signal determines a duration of a variable pulse width programming signal; adjusting the initial voltage of the variable pulse width primeval signal, wherein the initial voltage is adjusted based on a binary digital input and a ReRAM memory cell array supply voltage, and wherein the adjusting determines an output voltage of the variable pulse width programming signal; routing the variable pulse width programming signal to a portion of the ReRAM memory cell array, based on a ReRAM operation; and programming the portion of the ReRAM memory cell array, using the variable pulse width programming signal that was routed.

As can now be appreciated, disclosed implementations provide control for a resistive random-access memory (ReRAM) memory cell array with advancements that address the shortcomings of conventional designs. Unlike typical PLL-based systems, which are limited by fixed frequency and duty cycle constraints, disclosed implementations incorporate a highly flexible PWM generator that dynamically adjusts pulse widths across a wide range (e.g., 10 nanoseconds to 10 milliseconds) to accommodate set, reset, and form operations. Additionally, traditional voltage regulation methods rely on static configurations, whereas disclosed implementations employ a combination of DACs and amplitude changers to achieve dynamic, operation-specific voltage scaling. Disclosed implementations can provide an optimized layout that minimizes physical area and energy requirements compared to traditional designs, enabling superior compactness that facilitates simplified integration into larger systems. Moreover, the amplitude changer combines PWM and DAC outputs to create a filtered signal that can provide clean and precise control for ReRAM programming. Thus, disclosed implementations can enable improved operation and flexibility for electronic devices that use ReRAM memory cell arrays.

Each of the above methods may be executed on one or more processors on one or more computer systems. Embodiments may include various forms of distributed computing, client/server computing, and cloud-based computing. Further, it will be understood that the depicted steps or boxes contained in this disclosure’s flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagram and flow diagram illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions—generally referred to herein as a “circuit,” “module,” or “system”— may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A method for memory control comprising:
accessing a resistive random-access memory (ReRAM) memory cell array;
generating a variable pulse width primeval signal, wherein the variable pulse width primeval signal is generated using a pulse width modulator, wherein the variable pulse width primeval signal is generated at an initial voltage, and wherein a width of the variable pulse width primeval signal determines a duration of a variable pulse width programming signal;
adjusting the initial voltage of the variable pulse width primeval signal, wherein the initial voltage is adjusted based on a binary digital input and a ReRAM memory cell array supply voltage, and wherein the adjusting determines an output voltage of the variable pulse width programming signal;
routing the variable pulse width programming signal to a portion of the ReRAM memory cell array, based on a ReRAM operation; and
programming the portion of the ReRAM memory cell array, using the variable pulse width programming signal that was routed.

2. The method of claim 1 wherein the generating a variable pulse width programming signal is controlled by a pulse count input.

3. The method of claim 2 wherein the pulse count input comprises a 4-bit binary input.

4. The method of claim 2 wherein the pulse count input generates a variable pulse width programming signal having a duration in a range of 0.2ns to 10ms.

5. The method of claim 1 wherein the adjusting an initial voltage of the variable pulse width programming signal is performed by a voltage amplifier.

6. The method of claim 5 wherein the voltage amplifier is controlled by a digital-to-analog converter (DAC).

7. The method of claim 6 wherein the DAC is programmed by a binary digital input.

8. The method of claim 7 wherein the binary digital input is converted to an analog voltage to effect the controlling of the voltage amplifier.

9. The method of claim 7 wherein the binary digital input comprises 3 bits.

10. The method of claim 7 wherein the binary digital input determines the output voltage.

11. The method of claim 1 wherein the routing the variable pulse width programming signal enables control of a ReRAM memory cell array wordline, a ReRAM memory cell array bitline, and a ReRAM memory cell array select line.

12. The method of claim 11 wherein control of the ReRAM memory cell array wordline, the ReRAM memory cell array bitline, and the ReRAM memory cell array select line is managed by logic blocks comprising the same generating, adjusting, and routing functionality.

13. The method of claim 1 wherein the generating, the adjusting, and the routing are determined dynamically on a per programming operation basis.

14. The method of claim 13 wherein the per programming operation basis corresponds to a ReRAM set operation, a ReRAM reset operation, or a ReRAM form operation.

15. The method of claim 14 wherein the ReRAM set operation provides a variable pulse width programming signal voltage of 2V+/-10%.

16. The method of claim 14 wherein the ReRAM reset operation provides a variable pulse width programming signal voltage of 3.3V+/-10%.

17. The method of claim 14 wherein the ReRAM form operation provides a variable pulse width programming signal voltage of 4.3V+/-10%.

18. The method of claim 14 wherein a ReRAM programming operation signal voltage is greater than a supply voltage for the ReRAM memory cell array.

19. The method of claim 1 wherein the routing the variable pulse width programming signal is gated to the portion of the ReRAM memory cell array being programmed using one or more pass device switches.

20. A computer program product embodied in a non-transitory computer readable medium for memory control, the computer program product comprising code which causes one or more processors to generate semiconductor logic for:
accessing a resistive random-access memory (ReRAM) memory cell array;
generating a variable pulse width primeval signal, wherein the variable pulse width primeval signal is generated using a pulse width modulator, wherein the variable pulse width primeval signal is generated at an initial voltage, and wherein a width of the variable pulse width primeval signal determines a duration of a variable pulse width programming signal;
adjusting the initial voltage of the variable pulse width primeval signal, wherein the initial voltage is adjusted based on a binary digital input and a ReRAM memory cell array supply voltage, and wherein the adjusting determines an output voltage of the variable pulse width programming signal;
routing the variable pulse width programming signal to a portion of the ReRAM memory cell array, based on a ReRAM operation; and
programming the portion of the ReRAM memory cell array, using the variable pulse width programming signal that was routed.

21. An apparatus for memory operation control comprising:
a resistive random-access memory (ReRAM) memory cell array, wherein the ReRAM array comprises wordlines, bitlines, and select lines;
a first control logic coupled to the wordlines of the ReRAM array, wherein the first control logic drives the wordlines of the ReRAM array, based on a first selection input;
a second control logic coupled to the bitlines of the ReRAM array, wherein the second control logic drives the bitlines of the ReRAM array, based on a second selection input;
a third control logic coupled to the select lines of the ReRAM array, wherein the third control logic drives the select lines of the ReRAM array, based on a third selection input; and
input decoding logic coupled to the first control logic, the second control logic, and the third control logic, wherein the input decoding logic enables ReRAM operation selection, and wherein an operation that was selected is performed with a variable pulse width, adjusted voltage programming signal.
